(19) United States
(12) Patent Application Publication
(10) Pub. No.: US 2008/0157983 A1
(43) Pub. Date: Jul. 3, 2008

(54) Remotely Operable Game Call or Monitoring Apparatus

(75) Inventors: Ronald Rhea Dir, Sturtevant, WI (US); Edwin Thomas Horton, Wildwood, MO (US)

Correspondence Address: MILLER, MATTHIAS & HULL, ONE NORTH FRANKLIN STREET, SUITE 2350, CHICAGO, IL, 60606, US

(73) Assignee: Designlink, LLC, Sturtevant, WI (US)

(21) Appl. No.: 11/872,849

(22) Filed: Oct. 16, 2007

Related U.S. Application Data
(60) Provisional application No. 60/829,790, filed on Oct. 17, 2006.

(51) Int. Cl. G08B 21/18; H03G 3/00

(52) U.S. Cl. 340/573.2; 381/61

(57) ABSTRACT

A came call and/or monitoring apparatus is disclosed that includes a handheld central unit and one or more remote modules. The central unit includes a user input and a display screen, and communicates with the remote module(s). Each remote module is capable of generating a game call, taking an image, or executing some other function related to the hunting and monitoring of wildlife. The remote module may further be capable of communicating back to the central unit.

### CROSS-REFERENCE TO RELATED APPLICATION

This application claims the benefit of U.S. Provisional Application No. 60/829,790, filed Oct. 17, 2006.

### FIELD OF THE DISCLOSURE

The present disclosure generally relates to systems for monitoring and attracting wildlife, and more particularly to remotely operated apparatus for generating game calls.

### BACKGROUND OF THE DISCLOSURE

Various apparatus are known to assist in the tracking and/or hunting of animals. For example, game calling or decoy devices are known for attracting animals to a particular location for monitoring or hunting purposes. Such devices may include a decoy/call unit and a remote for controlling operation of the decoy/call unit. Additionally, monitoring systems are known for capturing images of animals present in a particular location. These monitoring systems may include an image capturing device, such as a digital camera, that is mounted in a desired location and a remote for controlling operation of the camera. Other items, such as location monitors (i.e., global positioning systems) and communication devices (e.g., two-way radio), may be used during tracking and/or hunting of game.

The conventional hunting and tracking devices noted above are overly cumbersome in that the user is required to carry a plurality of separate devices. When using decoy and image capturing systems, for example, the user must carry and operate two separate, dedicated remotes. The use of GPS and communication devices requires the user to handle and manipulate additional devices dedicated to an associated function. As a result, it is difficult to coordinate use of all of these devices, particularly when out in the field, when time may be of the essence.

Furthermore, known tracking and hunting devices have limited functionality. Conventional game calling systems, for example, typically have a single speaker or call/unit associated with the remote controller. Consequently, the effective area across which the game call travels is limited, as is the number of calls that can be simultaneously generated. It is also overly difficult to obtain status or other information on the call unit. The call unit is typically positioned remotely from the user, and therefore a user must typically walk to the unit and inspect it to make sure it is operating properly, has sufficient battery life, or obtain other diagnostic information. Such action is overly cumbersome and may spoil the hunting or monitoring area.

Accordingly, there is an ongoing demand for further contribution in this area of technology.

### BRIEF DESCRIPTION OF THE DRAWINGS

FIG. 1 is a schematic view of the hunting system;

FIG. 2 is a front view of a central unit;

FIG. 3 is a front view of a central unit with GPS capabilities;

FIG. 4 is a perspective view of a sound module;

FIG. 5 is a perspective view of a camera module;

FIG. 6 is a perspective view of a camera module with GPS capabilities;

FIG. 7 is a perspective view of the central unit of FIGS. 2 and 3 showing the display and visual indicators;

FIG. 8 is a diagrammatic view of the circuitry within the hand held devices illustrated in FIGS. 2 and 3;

FIG. 9 is a diagrammatic illustration of the remote module of FIG. 4 and its circuitry;

FIG. 10 is a diagrammatic view of the camera module of FIG. 5 and its circuitry;

FIG. 11 is a diagrammatic view of the circuitry of the attractor remote module of FIG. 12;

FIG. 12 is a diagrammatic view of an attractor remote module;

FIG. 13 is a block diagram of a method of setting and storing hunt groups;

FIG. 14 is a block diagram of a method of customizing sounds used in a hunt group;

FIG. 15 is an exploded perspective view of a sound module; and

FIG. 16 is a side elevation view, in cross-section, of a sound module.

### DETAILED DESCRIPTION

Game monitoring and attracting systems are disclosed herein. These systems may be used to assist with tracking and/or hunting wildlife, such as bears, coyotes, bobcats, cougars, waterfowl, geese, elk, crow, deer, fish, or other game. The system includes a portable central unit and at least one remote module adapted to perform a tracking or hunting operation, such as generating a game call or monitoring wildlife in the area. In certain disclosed embodiments, the central unit and at least one remote module automatically establish a communication link that allows information to be sent both from the central unit to the remote module(s) and from the remote module(s) back to the central unit. The information may include command signals, status information, identifier information, or other data. In other disclosed embodiments, the system is used to attract game to a particular location by generating game calls. In certain embodiments, the system includes a central unit communicatively coupled to one remote module, while in other embodiments the system includes a central unit communicatively coupled to two or more remote modules. Where two or more remote modules are used, the central unit may independently manage each remote module. It will be appreciated that the systems and methods claimed herein may be used in different applications in addition to the monitoring and attracting uses disclosed herein.

For purposes of promoting an understanding the principles of this disclosure, reference will now be made to the embodiments illustrated in the drawings and specific language will be used to describe the same. It will nevertheless be understood that no limitation of the scope of this disclosure is thereby intended, as such alterations and further modifications in the illustrated device, and such further applications of the principles of this disclosure as illustrated therein being contemplated as would normally occur to one skilled in the art to which the disclosure relates.

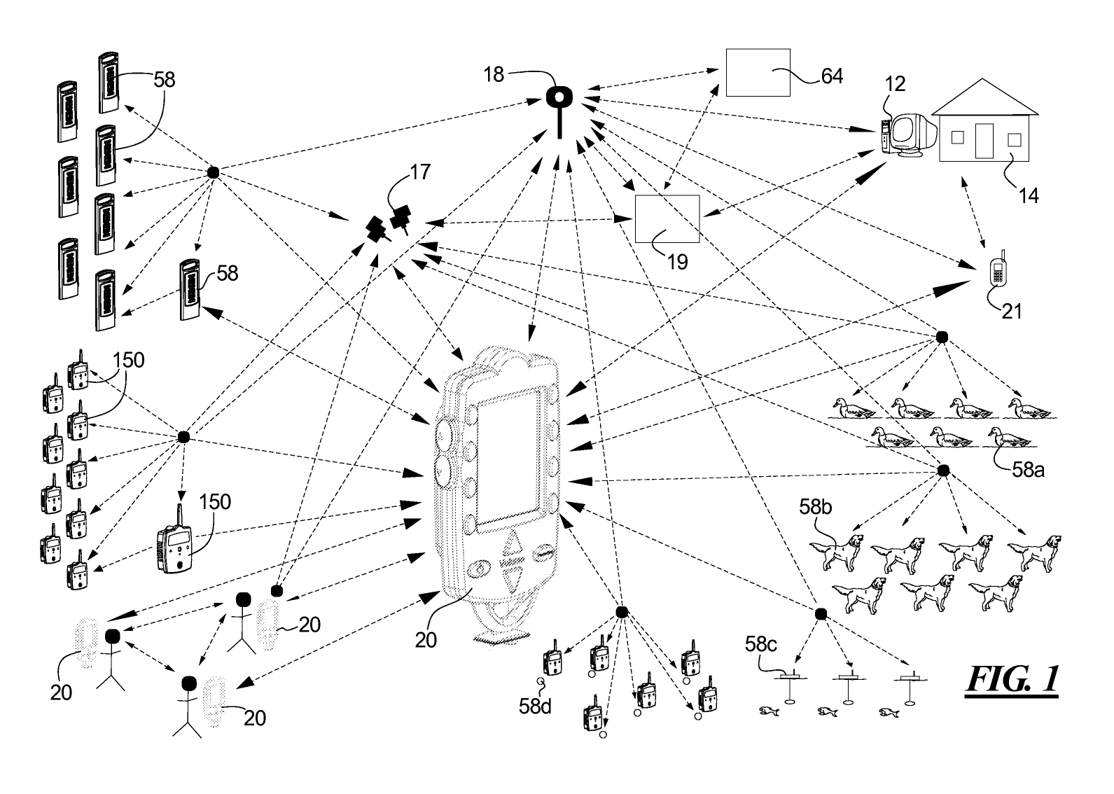

Referring to the drawings, FIG. 1 illustrates a system 10 to assist with the monitoring and/or hunting of game according to one embodiment of the current disclosure. System 10 includes a portable handheld device or central unit 20 and a plurality of remote modules (such as sound modules 58, camera modules 150, or other types of modules) interconnected by a communication system, such as a cellular phone system 18. Access between components in the network may be provided via the Internet 19. It should be appreciated that system 10 may include satellite or radio transmission or a GPS system 17, a single remote module, and/or a plurality of central units 20, such as a hunting group 20a. Furthermore, other communication systems and/or protocols, such as communication via a mobile phone 21, may be employed to establish communication between the components of the system 10.

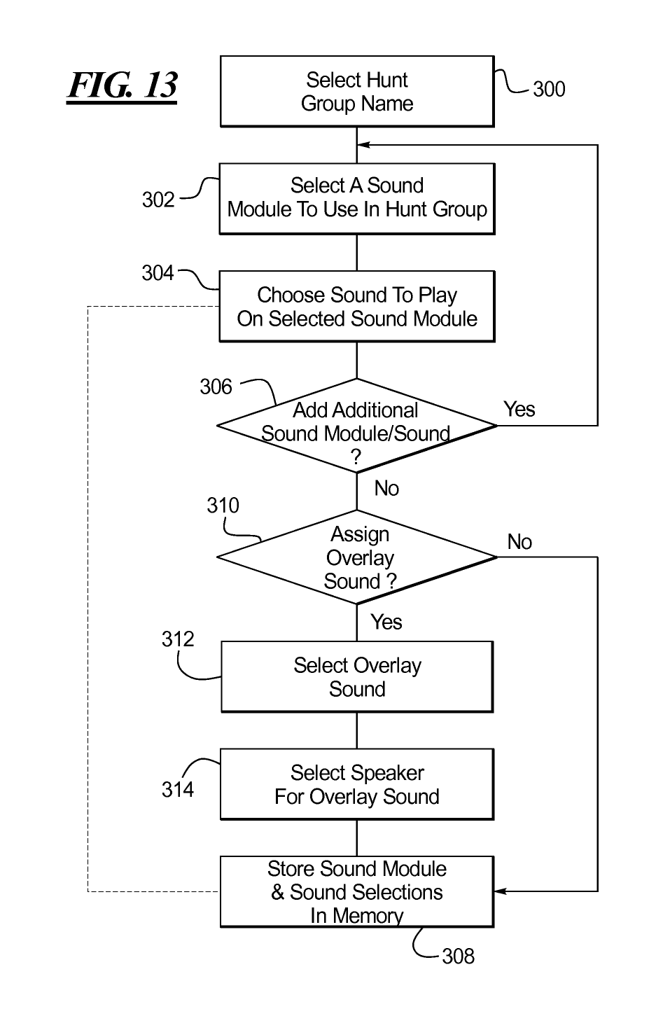

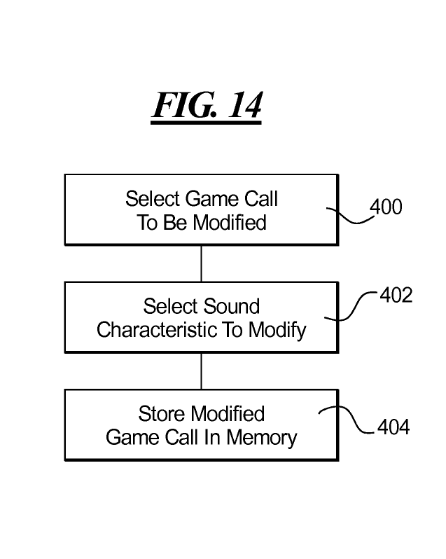

The system 10 enables a user to perform operations related to the monitoring and/or hunting of game, such as by attracting animals to and/or viewing animals within a particular area. The user selects at least one remote module to be placed in an area in which the animals are to be attracted to and/or monitored. The user may deploy multiple remote modules per forming the same function, a different function, or a combination thereof based on the location, type of animal to be attracted/monitored, terrain, weather, or various other factors. The remote modules are designed to attract animals into the area and/or monitor animal activity within the area. The remote modules may include sound modules 58 (FIGS. 5, 6 and 10), video or camera modules 150, attractor modules 250 (FIGS. 11 and 12), other types of modules, or combinations thereof. In one version, a plurality of sound and/or video modules are arranged to form a perimeter surrounding an area. In another version, remote modules are arranged such that they form a series of concentric perimeters, such as an outer perimeter and an inner perimeter, where the inner perimeter is within the outer perimeter. A sound 58 or attractor module 250 may be placed within at least the inner perimeter. Still further, a series of remote modules may be positioned along a path and used to incrementally draw animals to an area of interest.

As illustrated in FIG. 1, the central unit 20 may also communicate with one or more groups of remote modules that are adapted for a particular purpose. For example, the central unit 20 may communicate with a group of remote decoy units 58a, which may be duck or other types of decoys. Additionally or alternatively, the central unit 20 may communicate with one or more dog collar units 58b, floating fishing units 58c, ice fishing units 58d, or other types of remote modules adapted for a specific application.

The user employs the central unit 20 to activate and/or interact with the remote modules by choosing command options displayed on the central unit 20. Alternatively or additionally, a computer 12 may be used to activate and/or interact with the remote modules. In one version, the computer 12 is used to transmit a command signal over a range of up to five miles to a base station 14 having a high gain antenna, which then relays the command signal to remote modules dispersed up to two miles away from the base station 14. In another version, the computer 12 is communicatively coupled to a data center 64 in which all of the transmissions are stored. Repetitive messages and sounds may be stored in a memory device of the computer 12 and may be retrieved as desired. It should be noted, however, that should a computer be operatively coupled to the game call apparatus, it need not provide communication and instead may simply be used for storage of data, sounds, or other ancillary information.

When the user activates the central unit 20, at least one command option is displayed thereon. The command options allow user interface to select the type of animal to be attracted/monitored, the remote module to be activated/deactivated, the sound(s) to be played by the sound module(s) 58 or viewing of pictures/video taken, real-time viewing/recording of images from a camera module 150. Additionally, the command options may allow the user to operate a cellular phone, two-way radio, GPS locator, topography maps, altitude sensor, temperature sensor, lunar phase detector, or wind speed sensor. Still further, the command options may allow a user to determine or operate a direction indicator, a distance indicator, a direction faced indicator, a battery life indicator for the remote modules and/or the central unit, a digital aiming system, an attractor control system, or a point/object plotting system of each remote module. The user selects the desired command option displayed thereon and the central unit 20 sends a command signal to the remote modules. The command signal from the handheld 20 activates the remote modules and causes them to produce sounds, take pictures, record video, make movements, or various other operations. The sounds and/or movements produced by the remote modules are designed to attract animals, while the pictures and video show the user what animals are in the area and when. The remote modules may repeat the sounds and/or movements made by the remote modules until a stop signal is sent to the remote module. Such repetition of sounds and/or movements may maintain the animals' attention, thereby allowing the user extra time for monitoring and/or hunting activities.

The central unit 20 may also track/locate animals and objects utilizing GPS transponders. In one version, the central unit tracks/locates a dog having a GPS transponder located in its collar. It should also be appreciated that the central unit 20 may allow for plotting paths into and out of a hunting area and/or entering variables including, but not limited to, wind direction, precipitation, water location, food location, natural barriers, lunar phase, and previous sightings to determine optimum locations for the user to setup or paths into the hunting area.

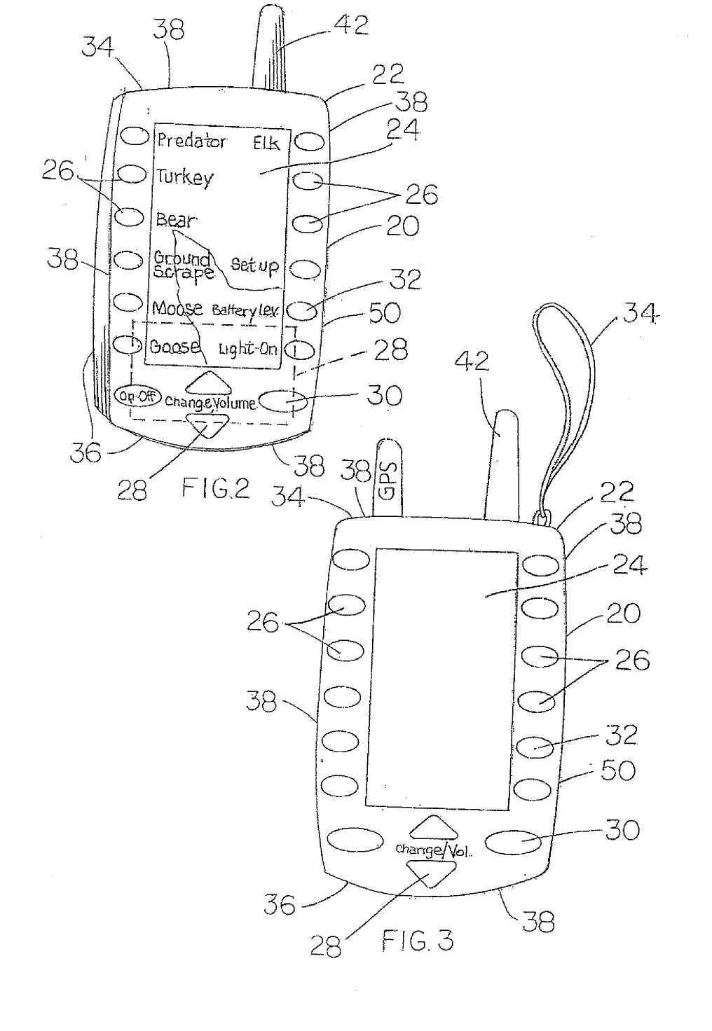

FIG. 2 illustrates central unit 20 according to one version of the current disclosure. The central unit 20 includes a body 22, a display 24, a plurality of buttons 26, a communication system 28, a controller 30, and a power supply 32. In other versions, central unit 20 may incorporate additional features such as a digital camera 150 or an altimeter, a thermometer, a lunar phase indicator, a digital compass, a Global Positioning System (GPS), a two-way radio, a cellular phone, a remote module/central unit battery life indicator, a wind-speed and direction indicator, a digital camera, a topographical indicator, an attractor control system, and/or an uplink for a satellite phone.

The body 22 includes a front surface 34 and rear surface 36 connected by a side wall 38. The body 22 is generally made of plastic. In other versions, the body 22 may be made of rubber, metal, or any semi-rigid material, rigid material, or combination thereof. The body 22 may include a tether, a clip, a strap, or other securing apparatus (not shown) that may be used to secure the central unit 20 to, for example, the user.

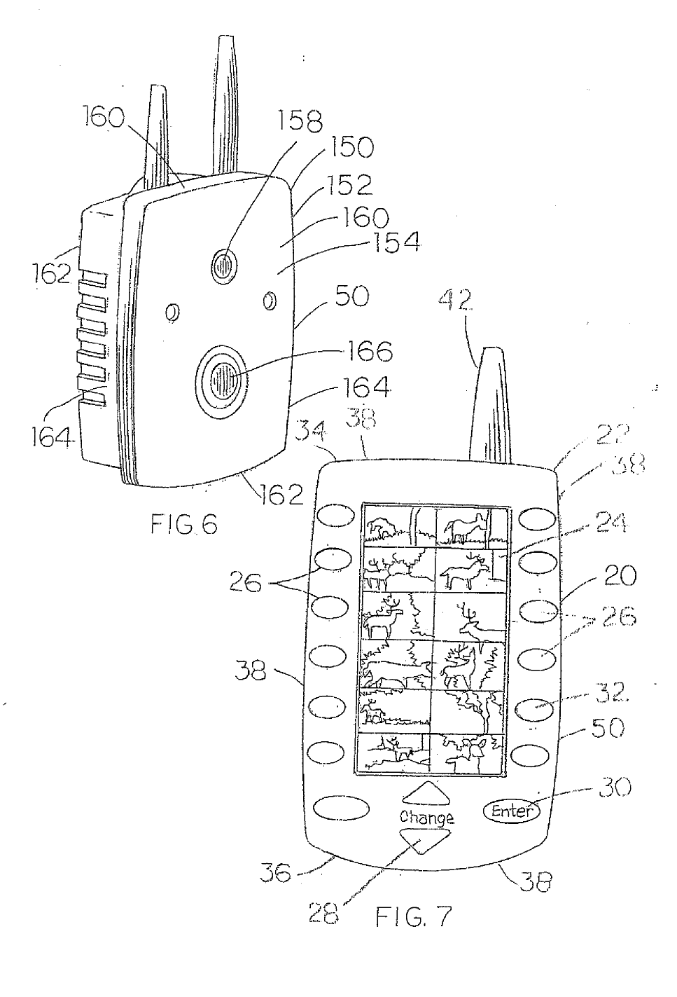

The display 24 is shown recessed in the front surface 34 of the body 22. It should be appreciated that the display 24 may be raised above or be flush with the front surface 34 of the body 22. It should also be appreciated that the display 24 may be in color and may be a liquid crystal, plasma, vacuum tube, touch-screen, or other type of display. The display 24 is used to display command options for controlling the remote modules. In other versions, the display 24 may also display pictures, video, text, and/or any other visual indicators used with the additional features previously described. See FIG. 7. In addition, the display 24 may be provided as a backlit LCD screen to permit use in low light conditions. In a preferred embodiment, the backlighting is red to reduce or eliminate the ability of an animal to detect the light.

A user interface is provided in the form of a plurality of buttons 26, which may protrude from the front surface 34 of the body 22 and which may be located along the perimeter of the display 24. In other versions, the plurality of buttons 26 may be a plurality of switches and/or may protrude from the sidewall 38 and/or bottom surface 36 of the body 22. In still other versions, the buttons 26 may be recessed or flush with the front surface 34 of the body 22 or may be incorporated into the display 24 or body 22. In further versions, the user interface may be provided directly on the display as a touchscreen, in which case the buttons 26 may be actuated by touching the display 24 with a finger or a selecting instrument such as a light pen. The buttons 26 are aligned such that they are adjacent to the command options displayed on the display 24. Selection of the command option may be accomplished by actuating the button 26 aligned with the desired command option.

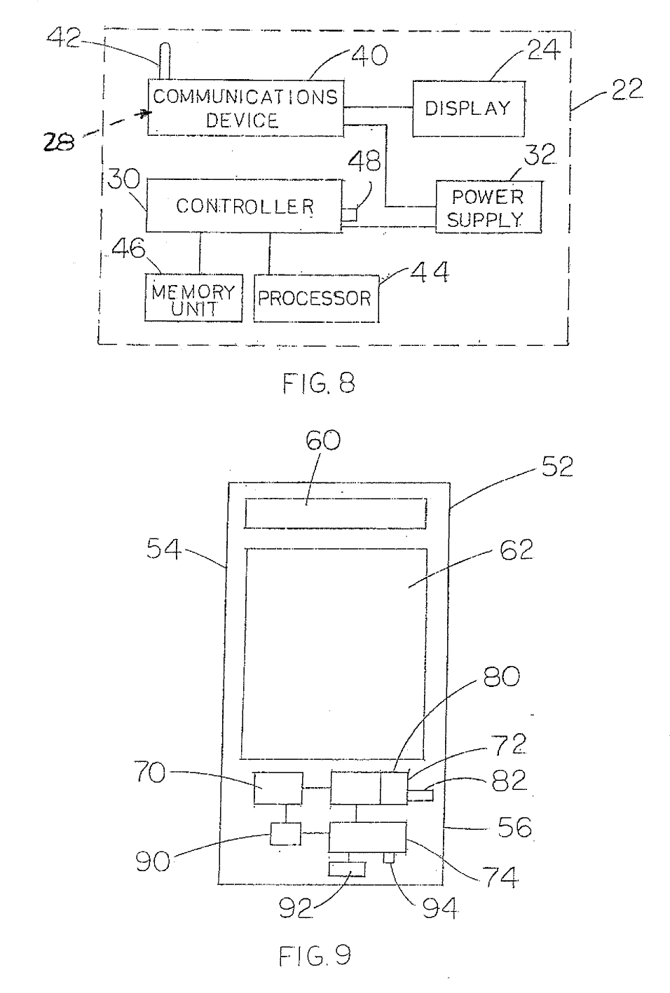

The central unit communication system 28 shown in FIG. 8 is contained within the body 22 and includes a communication device 40 with an antenna 42 that protrudes from one of the sides 38 of the body 22. It should be appreciated that the antenna 42 may be incorporated into or flush with the body 22 of the central unit 20. In other versions, central unit 20 may include a plurality of antennae 42 and communication devices 40 to accommodate additional features, such as GPS, as shown in FIG. 3. The communication device 40 preferably communicates bi-directionally, transmitting data to and receiving data from the plurality of remote modules using radio frequency (RF) communication, and therefore may include a transceiver or separate transmitter and receiver components. The communication device 40 may utilize other forms of communication such as a cellular phone network, a satellite transmission, ultrasound, magnetic, infrared (IR), microwave, Bluetooth, or other communication methods, protocols, and frequencies. It should also be appreciated that the device 40 may communicate with the computer 12 or another central unit 20.

The controller 30 is contained within the body 22 and includes a processor 44. The controller 30 may also include a memory unit 46 that stores command options thereon and a data port 48 for programming and erasing the memory unit 46. It should be appreciated that data port 48 may communicate with remote modules, other central units, or computers to update programming, exchange pictures and/or video, or other information. In one version, the processor 44 is a programmable logic controller (PLC). In other versions the processor 44 may be an embedded circuit, a microprocessor, a “proportional, integral, derivative” loop controller (PID controller), or other programmable or embedded controllers. When the central unit 20 is powered on, the processor 44 interacts with the display 24 to display command options thereon.

The power supply 32 may be an alkaline battery, a lithium battery, a lithium composite battery, a lead acid core battery, nickel metal hydride battery, or any other rechargeable or non-rechargeable batteries. In other versions, the power supply 32 may be a rechargeable 9v lithium ion battery.

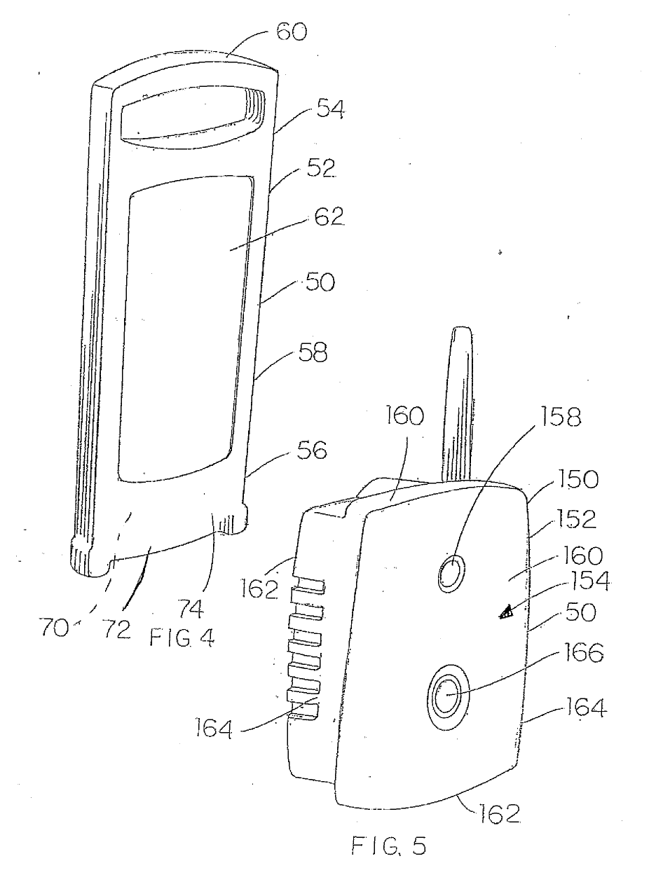

FIG. 4 illustrates a remote module in the form of a sound module 58. The sound module 58 generates game calls to attract animals to a particular location. Game calls are defined herein as sounds commonly heard in the wild, including mating calls, noises made by distressed animals, background animal noises, and other naturally occurring sounds. Additionally, a game call may comprise a non-naturally occurring sound that is attractive to animals. One example of such a non-naturally occurring sound is an emergency vehicle or fire truck siren that is attractive to coyotes. The sound module 58 includes a housing 52 with a top portion 54 and a base portion 56. The housing 52 is generally made of plastic, but may be composed of other materials as previously described.

The top portion 54 includes a handle 60 and speaker 62. It should be appreciated that top portion 54 may omit the handle 60 or may instead include other carrying or securing structures as previously described. In a currently preferred embodiment, the speaker 62 is a planar speaker that allows for sound waves to propagate from both sides of the housing 52 and is retained and secured by its edges within the top portion 54. In other versions, speaker 62 may be a ribbon system speaker, a piezoelectric speaker, or other speaker or combination of loudspeakers.

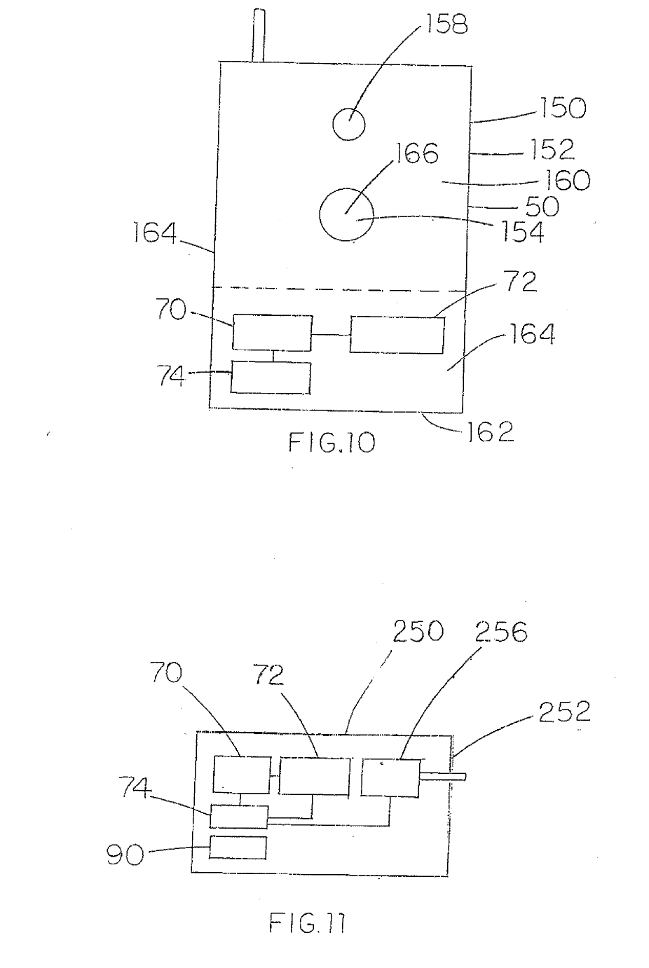

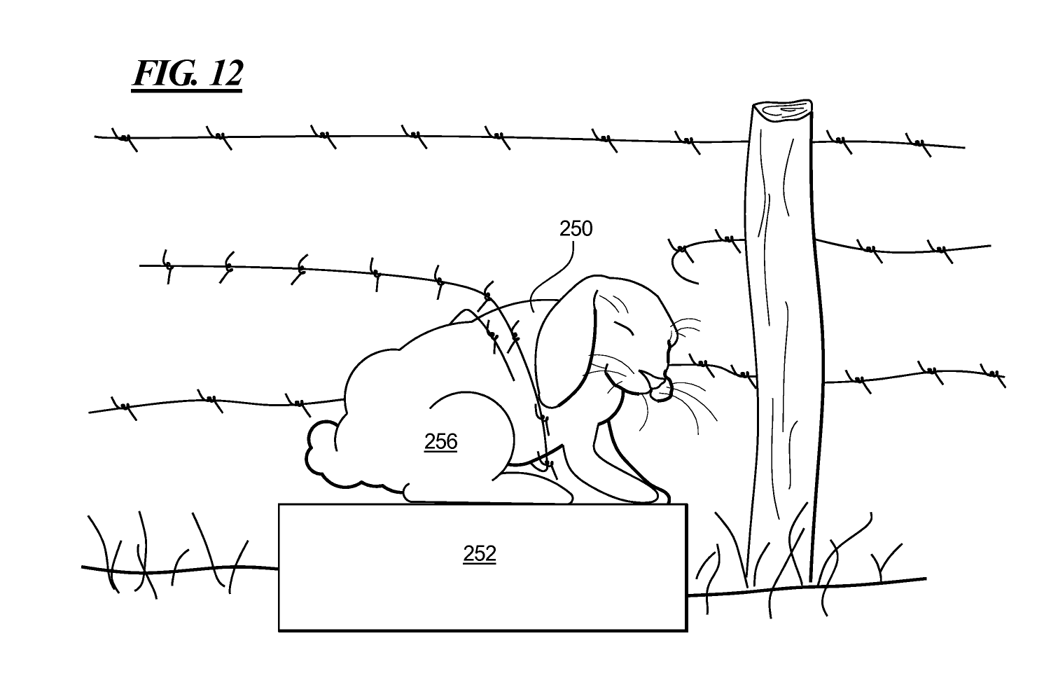

The base portion 56 includes a power supply 70, a communication system 72, and a controller 74 (FIG. 9). In one version, the power supply 70 is a rechargeable 9v lithium ion battery. In other versions, power supply 70 may be other rechargeable or non-rechargeable batteries as previously described.

As best shown in FIG. 9, the remote module communication system 72 includes a communication device 80 and an antenna 82. It should be appreciated that antenna 82 may be incorporated into the base portion 56 and/or may include a plurality of antennae 82 to accommodate additional features, such as GPS. The communication device 80 prefer ably communicates bi-directionally, transmitting data to and receiving data from the central unit 20, another remote module, or other device, preferably using radio frequency (RF) communication, and therefore it may include a transceiver or separate transmitter and receiver components. The communication device 80 may utilize other communication methods, protocols, and frequencies previously described. The communication device 80 may receive a signal from the communication system 28 in the central unit 20 through the antenna 82, and may forward that signal to the controller 74.

The controller 74 is contained within the base portion 56 and includes a processor 90, a memory unit 92, and a data port 94. In one version, the processor 90 is a PLC. In other versions, the processor 90 may be other programmable or embedded controllers as previously described. When the processor 90 receives the signal from the communication system 72, the processor 90 analyzes the signal and performs the functions specified in the signal.

The controller 74 is operable to carry out a variety of functions. In response to incoming signals sent by the central unit 20, the processor 90 may execute one or more commands carried by the signal. The commands may relate to the operation of the sound module 58, such as to raise or lower volume, repeat a particular game call, combine two or more game calls to generate a unique sequence of calls, turn the module on or off, or to perform some other function. A silent interval period may separate the sounds or calls, whether repeated or different, and the controller 74 may be operable to modulate the length of the silent intervals in a given repeating sound pattern or sequence of different sounds

Additionally, the controller 74 is operable to cause the communication device 80 to forward information regarding the sound module 58 to the central unit 20. The information may include status information, such as power supply life, signal strength, or identification of the current or most recent game call(s). Additionally or alternatively, the information may include identification information associated with the module 58, such as the model number or a unique identifier assigned to the module. The information sent by the communication device 80 is received and processed by the central unit controller 30, which may be operable to cause the display 24 to present the information in a form that is readily recognizable and understood by the user, such as by showing text or icons on the display 24. Thus, the user may obtain status, identification, or other information regarding one or more sound modules 58 from the hand-held central unit 20, rather than requiring direct physical inspection of the modules.

A central unit 20 and one or more remote modules may be programmed to automatically synchronize communications. As noted above, each of the central and remote modules is assigned a unique identifier, or priority code, which permits a user to identify which particular remote modules are communicating with the central unit 20. The central unit may be programmed to automatically search for and establish such communication in response to a certain command, such as upon powering up of the central unit 20. Accordingly, a user may quickly and easily associate a number of remote modules within range of the central unit 20 by powering down and then powering back up the central unit 20.

The memory unit 92 utilizes an Electrically-Erasable Programmable Read-Only Memory (EEPROM). In other versions, memory unit 92 may include a hard disk drive, flash memory, an Erasable Programmable Read-Only Memory (EPROM), an optical disk, or other non-volatile or volatile memory storage devices. The memory unit 92 may be programmed and/or erased through the data port 94. The data port 94 is configured to communicate over a Universal Serial Bus (USB). It should be appreciated that the data port 94 may be configured to communicate using RF, IR, a parallel port, a serial port, fiber optics, or other data communication methods.

A single central unit 20 may be operatively coupled to multiple sound modules 58 to create a variety of game call scenarios. In one exemplary application, the central unit 20 may control multiple sound modules 58 that are programmed to play the same sound. The sounds may be synchronized so that a uniform sound is generated from each speaker, thereby increases the call range. Alternatively, the sounds may be layered to mimic the sound of a plurality of the same animal within the hunting area. The multiple speakers may be positioned in various types of geometries that are suited to the various types of hunts to be conducted. In one embodiment, the speakers may be positioned along a path in order to lure prey to a particular location. In other embodiments, the speakers may be positioned in a circle, square, or other configuration around a particular hunting area.

Alternatively, the central unit 20 may control each of the sound modules 58 to play different sounds. For example, a first sound module may be programmed to play a crow sound, a second module a distressed rabbit sound, and a third module a young coyote sound. The sound modules may be placed around the desired hunting area to produce a composite sound having increased attractiveness to the type of animal being hunted. Furthermore, one or all sound modules 58 associated with a group may be programmed to play two, three, four, or other multiples of different, overlayed sounds.

In a preferred embodiment, the sound module 58 is adapted to generate sound in a broad range of directions. Sound waves from a conventional horn speaker propagate in a conical shape and primarily in a single direction, thereby limiting the range across which the sounds are heard. The sound module 58 preferably uses a speaker that propagates sound waves in both a first direction and a second, opposite direction, thereby to increase the effective range of the module. In particular, it has been found that a planar speaker will produce the desired effect by simultaneously propagating sound waves in two opposite directions. A planar speaker will also produce sounds across a wider range of frequencies, with a higher dynamic range, and with less distortion than the horn or other speakers conventionally used in game call devices.

A user may store one or more “hunt groups” on the central unit 20, wherein each hunt group is particularly suited for a certain type of hunting excursion. For example, the central unit 20 may be programmed with a “deer hunt group” in which the central unit 20 controls an associated set of sound modules 58 to play a pre-programmed set of sounds that are attractive to deer. A schematic of how to develop and store two hunt groups to be played on two sound modules is provided at FIG. 13. A similar process may be used to develop one or more than two hunt groups that may be played on one or more than two sound modules 58.

Referring to FIG. 13, a name for the hunt group is selected at box 300. The name may identify the type of animal to be hunted, a particular location, or include other information that allows the user to recognize the hunt group. At box 302, a specific sound module is selected for use in the hunt group. As noted above, the sound modules 58 that are on and within range of the central unit 20 may be indicated on the central unit display. The user may select a sound module 58 from such a display, or use other means to associate a specific sound module 58 to the hunt group. Next, at box 304 the user selects a specific game call or sound to be played on the selected speaker. The sound is chosen from a list of available sounds. At decision box 306, the user is prompted to add an additional sound module. If the user desires to add another sound module, the steps shown in boxes 302 and 304 are repeated. Once all of the desired sound modules and sounds are selected, the hunt group is completed and may be stored at box 308.

Optionally, the hunt group may further be programmed to play an “overlay” sound on one or more speakers. An overlay sound is an additional sound that is assigned to a single sound module 58 and may be played simultaneously with or separately from the first sound assigned to that sound module 58. As shown in FIG. 13, the overlay feature is initiated by prompting the user to select whether or not to assign an overlay sound at decision box 310. If no, the user progresses to box 308 as mentioned above. If an overlay sound is desired, however, the user may select a desired overlay sound at box 312 and assign a specific speaker for that overlay sound at box 314. The steps shown in boxes 310, 312, and 314 are repeated for each overlay sound desired by the user.

The system further allows the user to modify characteristics of a game call and store the modified game call in memory for subsequent use. The modified game calls may stand alone or form a part of a hunt group. Some exemplary characteristics that may be modified include: volume, frequency, start time (i.e. sounds on different sound modules begin at the same time, at progressive intervals calculated to lure prey along a path, or randomly among the various sound modules 58), and space time (i.e., the interval of silence between game calls).

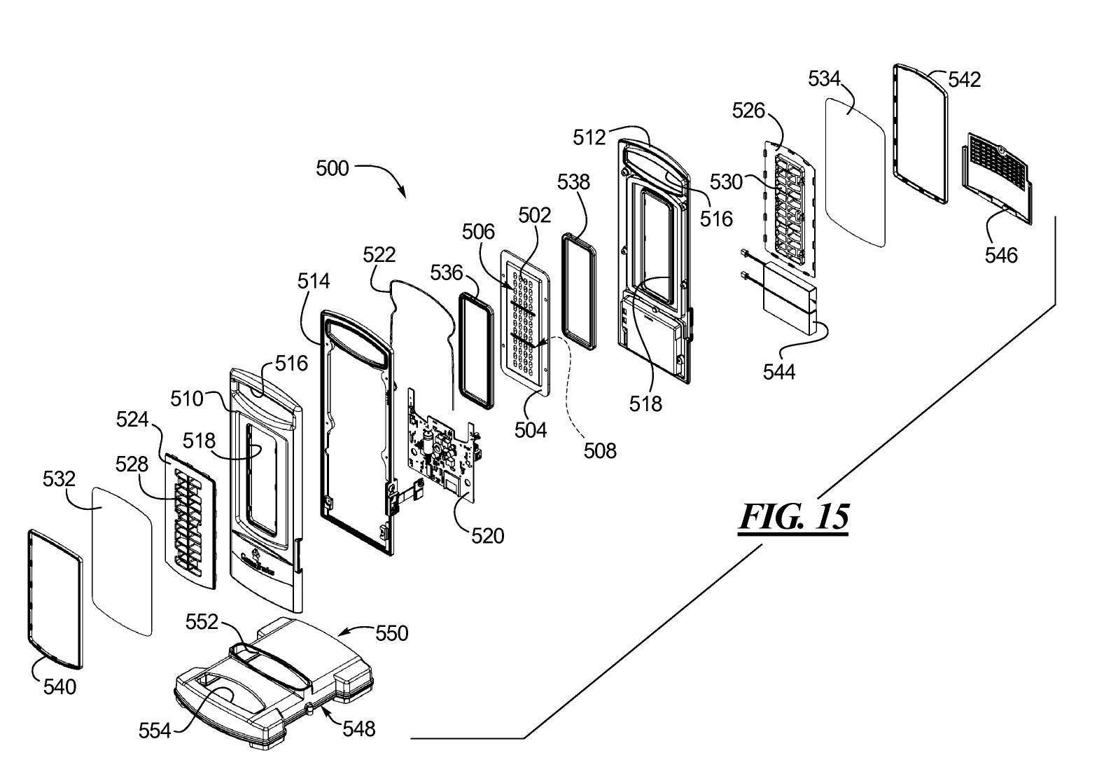

As schematically illustrated in FIG. 14, a game call may be customized by selecting a stored game call to be modified at box 400. A specific characteristic of that sound, such as volume level, pitch, start time, or other feature, may then be modified at box 402. The modifications made to the sound are then stored at box 404 so that the modified sound is available for use. In this way, the user may modify the game calls as desired, and those customized settings are stored for playback whenever the modified game call is subsequently used. Furthermore, this allows the game calls to be customized prior to use in the field.

When using a single sound module 58, the user may simply select one or more desired sounds to be played by the module. The selected sounds may be played in a continuous loop, may be randomly selected for replay, or a single sound from the group of assigned sounds may be selected for continuous repeat. The silent interval of time that elapses between the ending of an initial sound and the beginning of an immediately subsequent sound is referred to herein as the “space” between sounds. The space time may also be modified as desired by the user and can be stored for future use in a selected hunt group. Additionally, should a user adjust the volume, pitch, space, or other default settings of a particular sound, those changes may be stored in memory and used the next time that sound is used. Still further, the sound modules 58 may be programmed to automatically modulate characteristics of a sound as it is repeated. For example, the volume and frequency of a sound may be modified to create a varied, more realistic game call. In one embodiment only the beginning and end portions of a sound are modified to produce the desired game sound variation.

Two-way communication between the central unit 20 and sound module 58 allows for confirmation that a sound has been played, which is particularly beneficial in long range applications where the user is too far away to hear whether a sound module 58 has generated a sound. When a sound play signal is received by the sound module 58, the sound module 58 may further be programmed to send a return signal confirming that the sound play signal was received, thereby notifying the user that the sound module 58 generated the selected sound. When the return signal is received by the central unit 20, it may notify the user in any desirable manner, such as by illuminating a graphic icon on the central unit display.

FIG. 5 illustrates a remote module in the form of a camera module 150. The camera module 150 includes a body 152, a camera 154, a power supply 70, a communication system 72, and a controller 74. The body 152 includes a front surface 160, a rear surface 162, and a side surface 164 connecting the front surface 160 and the rear surface 162. The body 152 is generally made of plastic, but may be composed of other materials as previously described. The body 152 may include other carrying or securing structures as previously described. The body may include an indicator 158 that may be used to locate the camera module 150. The indicator may utilize a sound, light, or other indication techniques or combinations thereof.

Referring to FIG. 10, the camera 154 is generally contained within the camera module 150 such that a lens 166 of the camera 154 is flush with the front surface 160 of body 152. In other versions, the lens 166 of the camera 154 may protrude or be recessed from the front surface 160 of the body 152. The camera 154 is generally a digital camera able to capture images, such as photographs and video. In still further versions, the camera 154 may only take videos and record them on video cassette, minidisk, or any other media, or only take photographs on film, in memory, or any other suitable image storage media.

The communication system 72 of the camera module 150 is communicatively coupled to the central unit 20, so that digital pictures and/or video may be sent to the central unit 20 to be viewed on the display 24. The pictures and/or video may also be sent to a computer, cell phone, or any other communication device having a graphic display capable of viewing images or display device capable of receiving the images. Still further, images may be automatically downloaded to a database for immediate or subsequent viewing. In addition, the communication system 72 may also transmit information regarding the camera module 150, such as the status or identifier information similar to that noted above with respect to the sound module 58, to the central unit 20. To achieve both data reception and transmission, the communication system 72 may include a transceiver, or may include separate components for receiving and transmitting.

In a preferred embodiment, the central unit 20 and remote modules automatically detect each other to establish an ad hoc network over which information may be transmitted. More specifically, the central unit communication system 28 and all remote module communication systems continuously or routinely check for other compatible units that are within range. When two or more units are within range of each other, the respective controllers are operable to establish a communication link therebetween for transmitting operation information, which may include unit status, identification, or other data. Thus, the central unit 20 is able to automatically detect a remote module, multiple remote modules, another central unit, or multiple other central units. Similarly, each remote module is able to automatically detect a central unit, multiple central units, another remote module, or multiple other remote modules. To help the hunter coordinate and monitor the various remote modules deployed in the field, the central unit 20 may be programmed to display a graphic identifying each remote module with which it is communicating. The graphic may further include an indication of signal strength, battery level, or other diagnostic information. Conversely, the user may determine when communication with a remote module is lost should the graphic associated with that remote module no longer be displayed.

A remote module, such as the sound module 58 or the camera module 150, may further include an auxiliary sensor for initiating or otherwise altering operation of the remote module. The sensor may be responsive to parameters that indicate the presence of an animal, such as a heat or motion sensor, or may be responsive to some other parameter, such as a sound sensor that is responsive to gun shots. In any of the foregoing, the sensor may be adapted to generate an alarm signal when the sensor senses the intended parameter. In an exemplary embodiment, the remote module 58 may be equipped with two auxiliary sensors, one on each side of the module. The central unit 20 may be programmed to illuminate a graphical icon when a parameter is sensed and the sensor generates the alarm signal. Where two sensors are provided, the icon may further include a directional indicator to general indicate which sensor generated the alarm signal.

The remote modules may be programmed with a hibernate mode which allows the modules to be deployed in the field well in advance of the intended hunt. In the hibernate mode, the remote modules are only partially functional to conserve battery power. The remote module processor 90 includes a timer that powers on the remote module after a given time period. If a central unit 20 is within range, the remote module will establish communication and remain on. If no return signal from a central unit 20 is received (meaning that a central unit is not within range), the remote module will return to a lower power consumption mode until the next time period has run, at which time it repeats the above power up and search steps. The time period may be a matter of seconds, such as 5 to 30 seconds, a matter of minutes, or a matter of hours, as needed. Thus, the hibernate mode conserves batter power, which allows the remote modules to be placed in the field well before the intended hunt time, thereby minimizing the possibility of the hunter leaving his/her scent in the hunting area.

The sound module may include water proofing structure to protect the speaker from wet environments. An exploded perspective view of a sound module 500 is illustrated in FIG. 15. The sound module 500 includes a speaker assembly that includes a speaker element 502, such as a planar speaker, mounted on an integral speaker frame 504. The speaker element 502 defines front and rear side surfaces 506, 508 adapted to generate sound waves.

A housing, having front and rear halves 510, 512 joined by a housing gasket 514, encloses the speaker assembly. In the illustrated embodiment, the housing halves 510, 512 include handle apertures 516 to form a handle and central apertures 518 for permitting sound waves to pass through the housing. Also disposed in the housing is a circuit board 520 on which the various electrical components described above in conjunction with FIG. 9 are disposed. An internal antenna 522 is also disposed inside the housing.

The housing further includes front and rear inner side panels 524, 526 that extend over the speaker element front and rear side surfaces 506, 508. The inner side panels 524, 526 are acoustically permissive, that is they permit sound waves to pass. In the illustrated embodiment, each of the front and rear side panels 524, 526 includes a plurality of audio apertures 528 with adjacent, inwardly extending louvers 530. The audio apertures 528 are aligned with the speaker element 502 to allow sound waves to pass therethrough. The louvers 530 provide a barrier to protect the speaker element 502 from direct physical contact. In addition, the louvers 530 may be configured to direct liquid away from the speaker element 502. Each of the front and rear inner side panels 524, 526 defines an interior surface facing a corresponding speaker element side surface 506, 508 and an exterior surface facing away from the corresponding speaker element side surface 506, 508. While the exemplary embodiment uses structural opening to create acoustically permissive inner side panels 524, 526, it will be appreciated that other acoustically permissive means, such as acoustically permissive material, may be used to form the inner side panels.

Additionally, the housing may include front and rear outer side panels 532, 534 which extend over the exterior side surface of front and rear inner side panels 524, 526, respectively. The outer side panels 532, 534 are also acoustically permissive. In the exemplary embodiment, the outer side panels 532, 534 comprise a water repellant cloth material, such as polyspandex having a water repellant additive. The combination of the inner panels 524, 526 and outer panels 532, 534 improve the water resistance of the speaker module 500, thereby facilitating use in the rain or other wet environments.

The speaker module 500 may further include front and rear speaker gaskets 536, 538 to further improve the water resistance. When the housing is assembled, each speaker gasket 536, 538 is disposed in liquid tight sealing contact between a speaker element side surface 506, 508 and a corresponding housing inner side panel 524, 526. Each speaker gasket 536, 538 extends around a periphery of an associated speaker element side surface 506, 508. Accordingly, the speaker gaskets 536, 538 provide additional water resistance to the speaker assembly.

FIG. 15 shows additional components of the exemplary sound module 500. Front and rear bezels 540, 542 are shown for holding the outer side panels 532, 534 in place. Additionally, a battery 544 and battery door 546 are shown. Still further, a base 548 is shown that defines a sleeve 550 sized to receive a top portion of the speaker housing. When the speaker housing is removed from the sleeve 550, a bottom portion of the speaker housing may be inserted into a receptacle 552 formed in the base 548 to stand the housing upright for use in the field. While the base 548 is illustrated supporting a single housing, it will be appreciated that the base 548 may be modified to have additional receptacles 552, thereby to support multiple speaker housings. The base 548 further defines a handle aperture 554 sized to align with the handle apertures 516 of the housing, so that the handle and base may be easily carried together when not in use.

Certain types of speakers, such as planar speakers, may require additional amplification to generate sufficient volume for game call applications. The use of a larger amplifier generates more heat inside the housing, and therefore increases the risk of shorting electrical connections. Furthermore, it is desirable to minimize the overall thickness of the sound module, and therefore the amplifier is typically placed in close proximity to, and often on the same circuit board as, other electrical components.

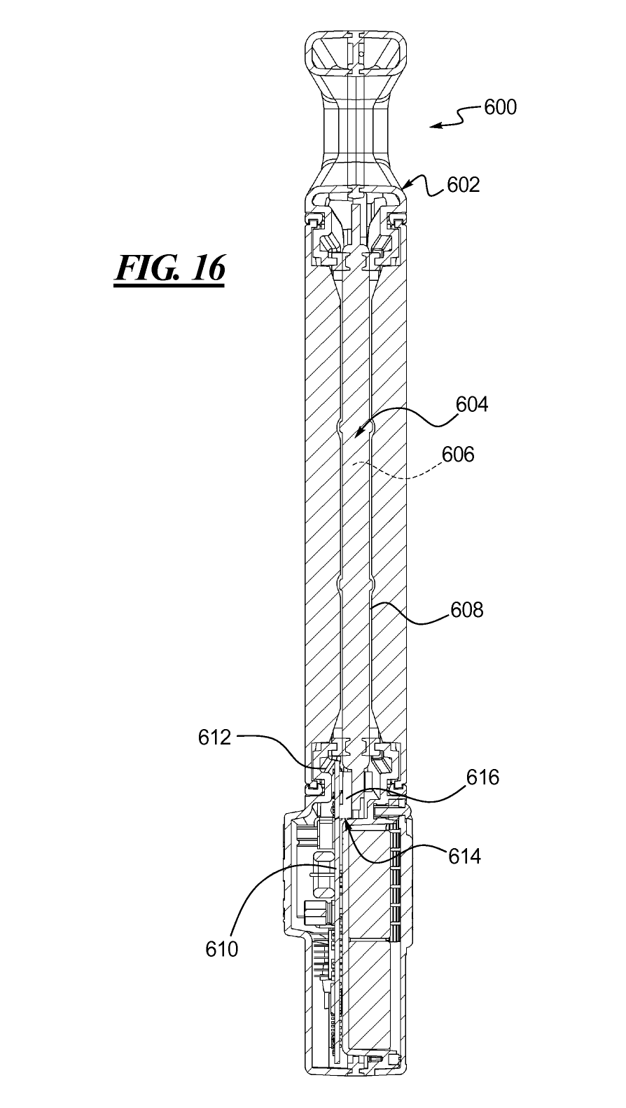

In view of the foregoing, the sound module may include a heat sink to direct heat generated by the amplifier away from the other electrical components of the sound module FIG. 16 illustrates a side elevation view, in cross-section, of a sound module 600 similar to the sound module 500 of FIG. 15. The sound module 600 includes a housing 602 and a speaker 604 disposed in the housing 602. The speaker 604 includes a speaker element 606, such as a planar speaker, coupled to a speaker frame 608. A circuit board 610 carrying a plurality of electrical components is also disposed in the housing 602. One of the components provide on the circuit board is an amplifier 612 which is operably coupled to the speaker element 606. A heat sink 614 is also disposed in the housing 602 and positioned adjacent the amplifier 612. In the exemplary embodiment, the heat sink 614 comprises a plate 616 of thermally conductive material that is preferably resistive to electrical current, such as aluminum. As illustrated, the plate 616 may be mounted on the same circuit board 610 as the amplifier 612.

The heat sink 614 may further include additional structure to improve the thermally conductive properties of the heat sink 614. In the exemplary embodiment, the plate 616 is in direct contact with the speaker frame 608. The speaker frame 608 may also be formed of a thermally conductive material, such as aluminum, but need not necessarily be electrically resistive since it is positioned farther away from the electrical components on the circuit board 610. As a result, the speaker frame 608 may form part of the heat sink 614.

In a further embodiment, an attractor module 250 includes a visually stimulating effect in addition to the game call, camera, or other game hunting/tracking components described above. As best shown in FIGS. 11 & 12, the attractor module 250 may include a speaker to simulate the noises, food, mating rituals, and/or other sounds that the game may find attractive. The attractor module 250 includes a base 252, an attractor simulator 256, a power supply 70, a communication system 72, and a controller 74. In one version, the attractor simulator 256 includes a moving arm carrying a game decoy, such as a robotic rabbit, that is secured to the base 252. In the illustrated embodiment, the robotic rabbit appears to be caught in a barbed-wire fence. The speaker may generate noises consistent with a rabbit caught in such a predicament. Thus, the attractor module 250 may more successfully attract the attention of a predator within range by generating calls observable by more than one sense, in this case both sight and sound. Additionally or alternatively, the attractor module 250 may include components that stimulate additional senses, such as a scent dispenser for producing an odor that may attract game. The attractor simulator 256 may include a universal base chassis and a set of simulated or real animal skins to change the external appearance of the simulator 256. The set of skins may include a rabbit skin, a squirrel skin, a ground hog skin, a raccoon skin, or skins of other common prey animals. Still further, the attractor simulator 256 may have the appearance of a duck decoy that bobs and moves in the water.

The attractor module 250 may be controlled by the user through the central unit 20, such as by using the buttons 26 or display 24. The central unit 20 may also use a computer program or a control pad to move the trapped rabbit of the attractor module 250. The program may be stored on the attractor module 250. In further versions, the attractor module 250 may be controlled by other devices such as a home computer, or remote controller.

To operate any one of the foregoing embodiments, the user may activate the central unit 20 by actuating a power button. The processor 44 of the controller 30 interacts with the display 24 to display command options thereon. The user selects a desired command option by actuating the corresponding button 26 located adjacent to the command option shown on the display 24. With the selection of the desired command option, the processor 44 interacts with the communication device 40 of the communication system 28 to transmit a signal to one or more selected remote modules, such as a sound module 58 or a camera module 150.

In this exemplary embodiment, the communication system 72 of the sound module 58 receives the signal, activates the sound module 58, and sends the signal to the controller 74. The processor 90 of the controller 74 analyzes the signal and queries the memory unit 92 for the specified data. Once the specified data is located on in the memory unit 92, the processor 90 outputs the signal to the speakers 62. The processor 90 sends a signal back to the central unit 20 through the communication system 72 confirming execution of the task. The processor 90 may continuously repeat the output signal to the speakers 62 until a stop signal is received from the central unit 20.

The processor 44 of the controller 30 also queries the memory unit 46. The processor 44 then interacts with the display 24 to display command options, thereon. The user selects a desired command option by actuating the corresponding button 26 located adjacent to the command option shown on the display 24. With the selection of the desired command option, the processor 44 interacts with the communication device 40 of the communication system 28 to transmit a signal to a remote module, such as a camera module 150.

The communication system 72 in the camera module 150 receives the signal and sends the signal to the controller 74. The processor 90 of the controller 74 analyzes the signal. If the user is asking for stored pictures or video, the processor queries the memory unit 92. Once the picture/video data is located on the memory unit 92, the processor 90 communicates the data through the communication system 72 to the central unit 20. If the user is asking for live footage or current pictures, the processor 90 inputs data from the camera 154 and sends the picture/video data back to the central unit 20 through the communication system 72.

The processor 44 of the controller 30 also queries the memory unit 46. The processor 44 then interacts with the display 24 to display command options thereon. The user selects a desired command option by actuating the corresponding button 26 located adjacent to the command option shown on the display 24. With the selection of the desired command option, the processor 44 interacts with the communication device 40 of the communication system 28 to transmit a command signal to a remote module, such as the attractor module 250.

The communication system 72 in the attractor module 250 receives the signal and forwards it to the controller 74. The processor 90 of the controller 74 analyzes the incoming signal and outputs a corresponding signal to the attractor simulator 256 to move the attractor simulator 256 and propagate the desired audio effect.

The above-described two-way communication between the central unit 20 and remote modules, and between multiple remote modules, enhances the game attraction and/or monitoring functions of the system 10. For example, communication between the central unit 20 and multiple sound modules 58 allows them to coordinate and synchronize the sounds generated by the modules 58. The feedback received during and/or after a game call is generated may be used to synchronize the speakers, to adjust volume of one or more modules 58, or to confirm that a noise was generated. Feedback may also be used to modulate the sounds generated by the speakers, thereby providing a series of unique calls that are more similar to natural calls or noises. The sounds may be modulated by varying starting and ending volumes, pitch, tone, direction, or other audio characteristics.

Each speaker in a system may also be programmed to generate a different animal sound to simulate a potentially target-rich area for a predator. For example, one speaker may generate a wounded rabbit sound, another speaker may generate a young coyote sound, and yet another speaker may generate a background sound such as a pecking woodpecker. The possibility of multiple potential targets within an area may prove irresistible to the predator, thereby increasing the chances of successfully attracting game to the desired area.

Systems including various combinations of the central and remote modules described above may be used or adapted for several applications in addition to the monitoring and attracting activities described above. As schematically illustrated in FIG. 1, remote modules may be attached to dog collars to assist with hunting dog training. In ice fishing applications, several remote modules may be positioned at various fishing sites to monitor the water for fish, the rod for movement (or “pop-up”), or other activity, which can be communicated back to a central unit 20. Similarly, floating remote modules may be placed in open water to monitor sites for fish movement or other activity.

In other versions, aspects previously mentioned may be combined together to form a single remote module having sound, camera, or other capabilities. The remote modules 58, 150 may include one or more auxiliary features. For example, the sound module 58 and camera module 150 may include two-way communication, cellular communication, GPS, satellite GPS, a dedicated data communication protocol. Furthermore, the sound module 58 may also include a digital or video camera, or both. Similarly, the camera module may include a game call speaker in addition to a digital camera, a video camera, or combination of digital and video cameras.

While the disclosure has been illustrated and described in detail in the drawings and foregoing description, the same is to be considered as illustrative and not restrictive in character, it being understood that only the preferred embodiment has been shown and described and that all changes and modifications that come within the spirit of the disclosure are desired to be protected. It should be understood that while the use of the word preferable, preferably or preferred in the description above indicates that the feature so described may be more desirable, it nonetheless may not be necessary and embodiments lacking the same may be contemplated as within the scope of the disclosure, that scope being defined by the claims that follow. In reading the claims it is intended that when words such as “a”, “an”, “at least one”, and “at least a portion” are used there is no intention to limit the claim to only one item unless specifically stated to the contrary in the claim further, when the language “at least a portion” and/or “a portion” is used the item may include a portion and/or the entire item unless specifically stated to the contrary.

What is claimed is:

1. A system for attracting game, comprising:
a remote module having a controller including a processor and memory, a receiver operably coupled to the controller, a transmitter operably coupled to the controller, a power supply operably coupled to the controller, and a game call generator, the game call generator including a single speaker element configured to propagate sound waves simultaneously in both a first direction and a second direction substantially opposite the first direction; and
a portable central unit including a transmitter communicatively coupled to the remote module receiver, a receiver communicatively coupled to the remote module transmitter, a controller operatively coupled to the transmitter and receiver and including a processor and memory, a power supply operably coupled to the controller, a display operatively coupled to the controller, and a user interface operably coupled to the controller.

2. The system of claim 1, in which the speaker element comprises a planar speaker element.

3. A system for monitoring game, comprising:
a remote module having a controller including a processor and memory, a receiver operably coupled to the controller, a transmitter operably coupled to the controller, a power supply operably coupled to the controller, an auxiliary sensor adapted to generate an alarm signal, and at least one game tracking component selected from a group of game tracking components including a game call generator, a digital camera, and a video camera; and
a portable central unit including a transmitter communicatively coupled to the remote module receiver, a receiver communicatively coupled to the remote module transmitter, a controller operatively coupled to the transmitter and receiver and including a processor and memory, a power supply operably coupled to the controller, a display operatively coupled to the controller, and a user interface operably coupled to the controller;
wherein the central unit processor is programmed to generate an alarm indicator on the central unit display in response to the alarm signal.

4. The system of claim 3, in which the alarm indicator comprises a graphical icon generated on the central unit display.

5. The system of claim 3, in which the auxiliary sensor comprises a heat sensor.

6. The system of claim 3, in which the auxiliary sensor comprises a motion sensor.

7. The system of claim 3, in which the auxiliary sensor is positioned on the remote module to have a detection range oriented along a first direction, the remote module further comprising a second auxiliary sensor positioned to have a detection range oriented along a second direction different from the first direction.

8. The system of claim 7, in which the alarm indicator further identifies the auxiliary sensor that generated the alarm signal.

9. A system for attracting game, comprising:
a remote module having a controller including a processor and a memory having a plurality of stored game calls, a receiver operably coupled to the controller, a transmitter operably coupled to the controller, a power supply operably coupled to the controller, and a game call generator operably coupled to the controller; and
a portable central unit including a transmitter communicatively coupled to the remote module receiver, a receiver communicatively coupled to the remote module transmitter, a user interface, and a controller operatively coupled to the transmitter, receiver, and user interface;
wherein the central unit controller is programmed to select a first game call from the remote module memory for playback on the remote module game call generator based on an input supplied by the user interface.

10. The system of claim 9, in which the central unit controller is further programmed to modify a characteristic of the first game call to obtain a modified first game call based on input from the user interface, and to save the modified first game call in the remote module memory.

11. The system of claim 10, in which the characteristic of the first game call comprises a volume level.

12. The system of claim 10, in which the characteristic of the first game call comprises a frequency.

13. The system of claim 10 in which the characteristic of the first game call comprises a space time between game calls.

14. The system of claim 9, in which the central unit controller is further programmed to select a second game call from the remote module memory for playback on the remote module game call generator based on an input supplied by the user interface.

15. The system of claim 14, in which the central unit controller is further programmed to generate a playback loop that includes the first and second game calls based on input from the user interface, and to save the playback loop in the remote module memory.

16. A sound module for use in a game call system, comprising:
a speaker including a speaker element having a first side surface adapted to generate sound waves; and
a housing enclosing the speaker, the housing including a first acoustically permissive inner side panel extending over the speaker element first side surface and defining an interior surface facing the first side surface and an exterior surface facing away from the first side surface, and a first acoustically permissive outer side panel extending over the first inner side panel exterior side surface.

17. The sound module of claim 16, in which the first inner side panel comprises a polymer material defining louvers.

18. The sound module of claim 17, in which the louvers are configured to direct liquid away from the speaker element first side surface.

19. The sound module of claim 16, in which the first outer side panel comprises a water repellant cloth.

20. The sound module of claim 16, in which the speaker element comprises a planar speaker.

21. The sound module of claim 16, further comprising a first gasket disposed in liquid tight sealing contact between the speaker element first side surface and the housing first inner side panel, the first gasket extending around a periphery of the speaker element first side surface.

22. A sound module for use in a game call system, comprising:
a housing;
a speaker disposed in the housing and including a speaker element coupled to a speaker frame;
an amplifier disposed in the housing and operably coupled to the speaker element; and
a heat sink disposed in the housing and positioned adjacent the amplifier.

23. The sound module of claim 22, in which the heat sink comprises a plate formed of a thermally conductive, electrically resistive material.

24. The sound module of claim 22, in which the heat sink directly contacts the speaker frame.

25. The sound module of claim 24, in which the speaker element frame comprises a thermally conductive material.
